(19) United States
(12) Patent Application Publication
(10) Pub. No.: US 2011/0291717 A1
(43) Pub. Date: Dec. 1, 2011

(54) SEMICONDUCTOR DEVICE

(76) Inventor: Kang-Youl Lee, Gyeonggi-do (KR)

(21) Appl. No.: 12/839,689

(22) Filed: Jul. 20, 2010

(30) Foreign Application Priority Data
May 27, 2010 (KR) 10-2010-0049604

(51) Int. Cl. H03L 7/06

(52) U.S. Cl. 327/158

(57) ABSTRACT

A semiconductor device includes a delay locked loop including a replica delay unit which is configured to delay a signal reflecting a delay amount of an output path of a signal, and a delay time compensator configured to compensate for a difference of a delay time between the replica delay unit and the output path by comparing an output signal of the replica delay unit and an output signal of the output path.

### CROSS-REFERENCE TO RELATED APPLICATIONS

The present application claims priority of Korean Patent Application No. 10-2010-0049604, filed on May 27, 2010, which is incorporated herein by reference in its entirety.

### BACKGROUND OF THE INVENTION

Exemplary embodiments of the present invention relate to a technology for designing a semiconductor device, and more particularly, to a semiconductor device including a delay locked loop (DLL).

Semiconductor memory devices are being developed to have increased operation speed as well as high degree of integration. To increase the operation speed, a synchronous semiconductor memory device has developed. The synchronous semiconductor memory device operates in synchronization with an external clock signal applied from the outside. The synchronous semiconductor memory device employs a delay locked loop (DLL) to output a data synchronized with a rising edge and a falling edge of the external clock signal. The delay locked loop generates an internal clock signal which is a signal obtained by delay-locking the external clock signal by a delay time that actually occurs inside a circuit.

FIG. 1 is a block diagram illustrating a structure of a known semiconductor memory device.

Referring to FIG. 1, the semiconductor memory device 100 includes an input buffer 110, a first output driver 120, a second output driver 130, and a delay locked loop 140. The input buffer 110 may be included in an input path, and it receives and buffers external clock signals CLK and CLKB, and outputs an internal clock signal INCLK. The first output driver 120 may be included in an output path, and it outputs a data DATA outputted from a memory cell (no shown) in synchronization with, for example, a delay locked internal clock signal DLLCLK. The second output driver 130 outputs the data DATA outputted from the first output driver 120 to a data pad DQ. The delay locked loop receives the internal clock signal INCLK and generates the delay locked internal clock signal DLLCLK by delaying the internal clock signal INCLK reflecting a first delay time tD1 which may be actually caused by the input buffer 110 and a second delay time tD2 which may be actually caused by the first output driver 120 and the second output driver 130.

FIG. 2 is a block diagram illustrating the semiconductor memory device 100 of FIG. 1.

Referring to FIG. 2, the input buffer 110 receives the external clock signals CLK and CLKB inputted from the outside, generates the internal clock signal INCLK, which may be a single-ended signal, and outputs the generated internal clock signal INCLK to the delay locked loop 140.

The first output driver 120 may include a pre-driver, and the second output driver 130 may include a main driver. In this case, the data DATA is outputted to the data pad DQ through the second output driver 130. Meanwhile, the second output driver 130 may include an off chip driver (OCD).

The delay locked loop 140 includes a delay line 141, a first replica delay unit 143, a second replica delay unit 145, a phase comparator 147, and a delay controller 149. The delay line 141 variably delays the internal clock signal INCLK by a third delay time tD3 and outputs the delay locked internal clock signal DLLCLK. The first replica delay unit 143 delays the delay locked internal clock signal DLLCLK by a modeled second delay time tD2 and outputs a first feedback clock signal FBCLK1. The second replica delay unit 145 delays the first feedback clock signal FBCLK1 by a modeled first delay time tD1 and outputs a second feedback clock signal FBCLK2. The phase comparator 147 compares a phase of the internal clock signal INCLK with a phase of the second feedback clock signal FBCLK2. The delay controller 149 controls the third delay time tD3 of the delay line 141 in response to an output signal of the phase comparator 147.

Hereafter, an exemplary operation of the semiconductor memory device 100 having the above-described structure will be described.

Once the external clock signals CLK and CLKB are transferred to the delay line 141 as the internal clock signal INCLK after being buffered in the input buffer 110, the delay line 141 delays the internal clock signal INCLK by the third delay time tD3 corresponding to a default value and outputs the delay locked internal clock signal DLLCLK.

In this situation, the first replica delay unit 143 receives a feedback signal, the delay locked internal clock signal DLLCLK, and delays the delay locked internal clock signal DLLCLK by the modeled second delay time tD2 to output the first feedback clock FBCLK1. Also, the second replica delay unit 145 delays the output signal FBCLK1 of the first replica delay unit 143 by the modeled first delay time tD1, and outputs the second feedback clock FBCLK2.

Then, the phase comparator 147 compares the phase of the internal clock signal INCLK outputted from the input buffer 110 with the phase of the second feedback clock FBCLK2 outputted from the second replica delay unit 145, and the delay controller 149 generates a control signal CTR for controlling the third delay time tD3 in response to the comparison result of the phase comparator 147.

The delay line 141 delays the internal clock signal INCLK by the third delay time tD3 in response to the control signal CTR and outputs the delay locked internal clock signal DLLCLK.

If the phase of the internal clock signal INCLK is synchronized with the phase of the second feedback clock FBCLK2 after repeating a series of the above operations, the third delay time tD3 of the delay line 141 is delay locked. This process may be represented by the following equations.

(n*tCK)+tD1=tD1+tD3+tD2+tD1 (1)

tD3=(n*tCK)−(tD1+tD2) (2)

DLLCLK=tD1+tD3=tD1+(n*tCK)−(tD1+tD2)=(n*tCK)−tD2 (3)

Here, the delay locked loop 140 synchronizes a rising edge of the internal clock signal INCLK, which is delayed by the first delay time tD1 compared with the external clock signal CLK, with a rising edge of the second feedback clock FBCLK2, which is delayed by a certain delay time (=tD1+tD3+tD2+tD1) compared with the external clock signal CLK (1). Therefore, the third delay time tD3 needed for delay locking equals to a time obtained by subtracting a sum of the first delay time and the second delay time (tD1+tD2) from the time corresponding to a clock period tCK of an integer (n) multiple. Meanwhile, the delay locked internal clock signal DLLCLK is a clock signal delayed by the sum of the first delay time and the third delay time (tD1+tD3) compared with the external clock signal CLK. The delay locked internal clock signal DLLCLK is toggled ahead by the second delay time tD2 from a rising edge of the external clock signal CLK. This state is a delay locked state.

In the delay locked state, the first output driver 120 outputs the data DATA, which is outputted from a memory cell (not shown), in synchronization with the delay locked internal clock signal DLLCLK, and finally outputs the synchronized data to the data pad DQ by controlling the second output driver 130. Here, the data DATA is delayed by the second delay time tD2 as the data DATA passes through the first output driver 120 and the second output driver 130, and when the synchronized data is outputted to the data pad DQ, it may be aligned to a clock edge of the external clock signal CLK.

Meanwhile, the semiconductor memory device 100 may perform an update process at every update period even after the third delay time tD3 for delay locking of the delay line 141, is determined. Since jitter may occur in the delay locked internal clock signal DLLCLK due to noise during the update process, the delay locking process described above may be repeatedly performed to compensate for the jitter.

However, whereas the delay line 141 reflects the variable third delay time tD3 in response to the control signal CTR of the delay controller 149, the first replica delay unit 143 and the second replica delay unit 145 reflects the modeled first and second delay times tD1 and tD2 which are fixed. However, since the first replica delay unit 143 and the second replica delay unit 145 are not the same circuits as actual circuits but modeled circuits, there may be a difference between the modeled circuits with the actual circuits due to the conditions of processes, voltage, and temperature (PVT). In particular, since the second output driver 130 may include a resistor which may be highly variable by the conditions of the processes, voltage, and temperature (PVT), such as an off chip driver (OCD), the difference from the second delay time tD2 modeled in the first replica delay unit 143 may increase. The difference may affect the delay locking of the delay locked loop 140, and as a result, the data DATA may not be precisely aligned with the external clock signal CLK when it is outputted to the data pad DQ.

### SUMMARY OF THE INVENTION

An embodiment of the present invention is directed to a semiconductor device that may stably operate regardless of a change in process, voltage and/or temperature (PVT).

In accordance with an embodiment of the present invention, a semiconductor device includes a delay locked loop including a replica delay unit which is configured to delay a signal reflecting a delay amount of an output path of a signal, and a delay time compensator configured to compensate for a difference of a delay time between the replica delay unit and the output path by comparing an output signal of the replica delay unit and an output signal of the output path.

In accordance with another embodiment of the present invention, a semiconductor device includes a delay line configured to delay a internal clock signal, an output path configured to receive an output clock signal of the delay line, and output a delay locked internal clock signal to an outside, a first replica delay unit configured to generate a first feedback clock signal by delaying the output clock signal of the delay line, a second replica delay unit configured to generate a second feedback clock signal by delaying the first feedback clock signal, a first phase comparator configured to compare the internal clock signal and the second feedback clock signal, a first delay controller configured to control a delay amount of the delay line according to the comparison result of the first phase comparator, a second phase comparator configured to compare the delay locked internal clock signal and the first feedback clock signal, and a second delay controller configured to adjust a delay amount of the first replica delay unit according to the comparison result of the second phase comparator.

In accordance with yet another embodiment of the present invention, a semiconductor device includes a delay locked loop including a replica delay unit which is configured to delay a signal reflecting a delay amount of an output path of a signal; a dummy output path configured to output a dummy output signal, wherein the dummy output signal has the substantially same phase as an output signal of the output path; and a delay time compensator configured to compensate for a difference of a delay time between the replica delay unit and the output path by comparing an output signal of the replica delay unit and the dummy output signal.

### BRIEF DESCRIPTION OF THE DRAWINGS

FIG. 1 is a block diagram illustrating a structure of a typical semiconductor memory device.

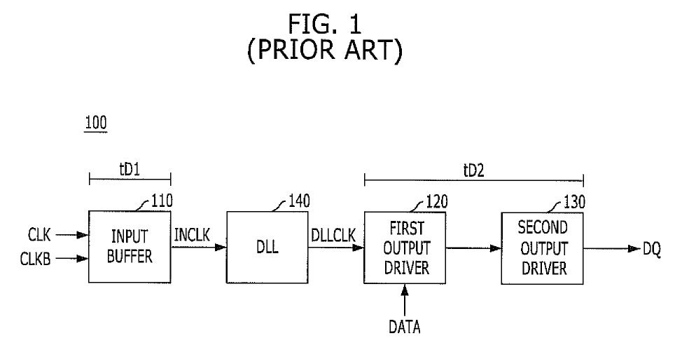

FIG. 2 is a detailed block diagram illustrating the semiconductor memory device of FIG. 1.

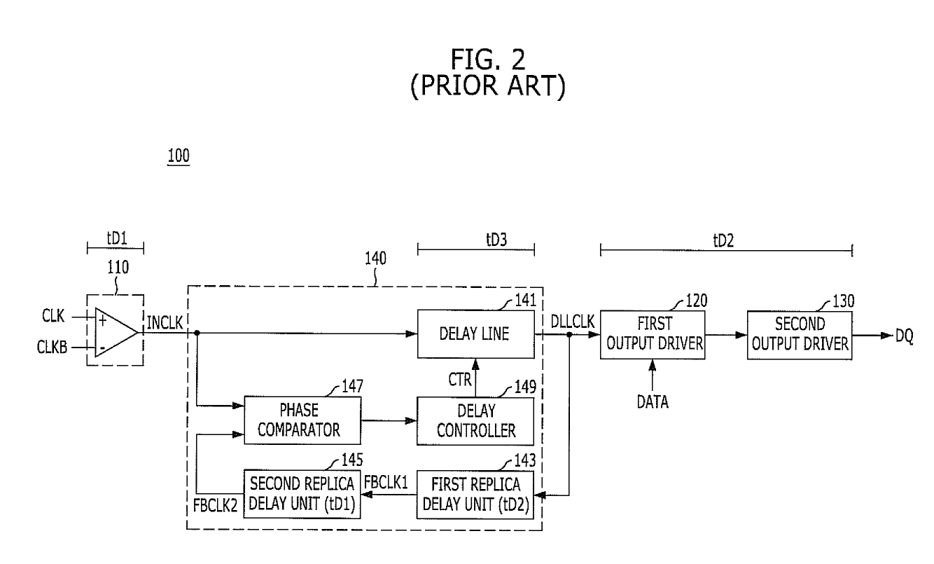

FIG. 3 is a block diagram illustrating a structure of a semiconductor memory device in accordance with a first embodiment of the present invention.

FIG. 4 is a detailed block diagram illustrating the semiconductor memory device of FIG. 3.

FIG. 5 is a block diagram illustrating a structure of a semiconductor memory device in accordance with a second embodiment of the present invention.

FIG. 6 is a detailed block diagram illustrating the semiconductor memory device of FIG. 5.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

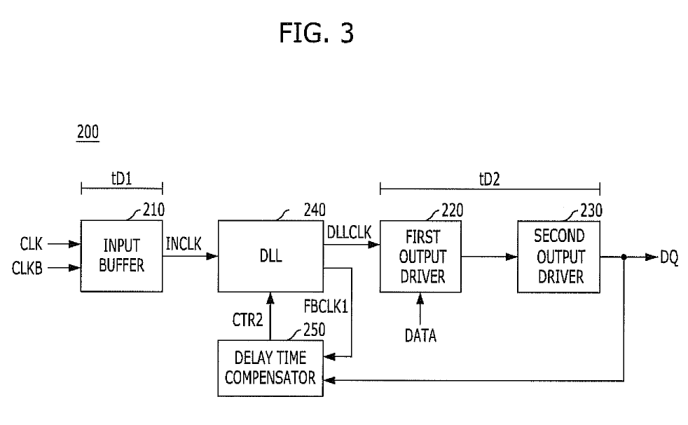

FIG. 3 is a block diagram illustrating a structure of a semiconductor memory device 200 in accordance with an exemplary embodiment of the present invention.

Referring to FIG. 3, the semiconductor memory device 200 includes an input buffer 210, first and second output drivers 220 and 230, a delay locked loop (DLL) 240, and a delay time compensator 250. The input buffer 210 is included in an input path and receives external clock signals CLK and CLKB from the outside and outputs an internal clock signal INCLK. The first and second output drivers 220 and 230 are included in an output path and synchronizes a data DATA outputted from a memory cell (not shown) with a delay locked internal clock signal DLLCLK and outputs a synchronized signal to a data pad DQ. The delay locked loop 240 receives the internal clock signal INCLK and generates the delay locked internal clock signal DLLCLK by reflecting a first delay time tD1 which occurs by the input buffer 210 and a second delay time tD2 which occurs in the first and second output drivers 220 and 230. The delay time compensator 250 adjusts the second delay time tD2 by using a first feedback clock signal FBCLK1 reflecting the second delay time tD2 and an output signal of the second output driver 230.

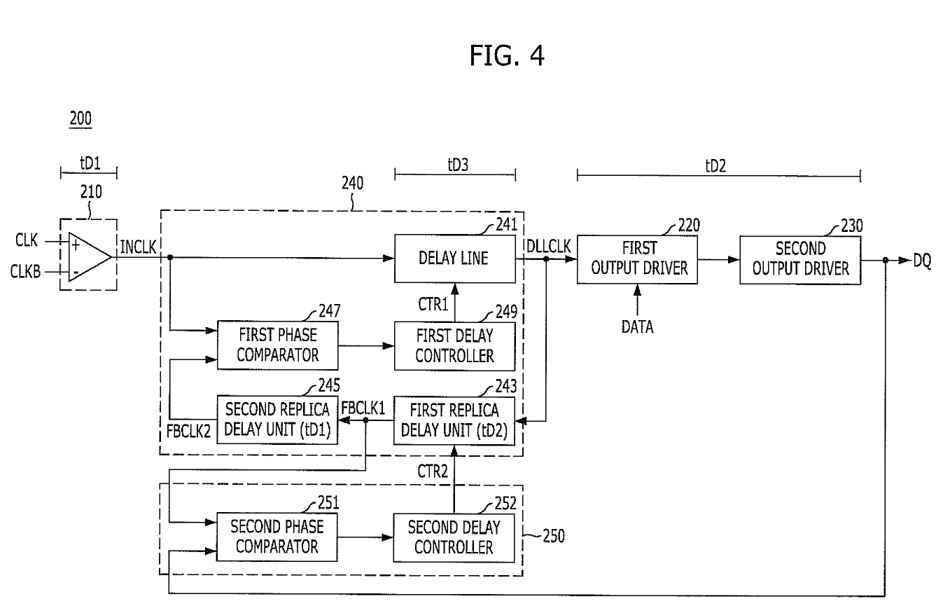

FIG. 4 is a detailed block diagram illustrating the semiconductor memory device of FIG. 3.

Referring to FIG. 4, the input buffer 210 receives the external clock signals CLK and CLKB inputted from the outside, generates an internal clock signal INCLK, which may be a single-ended signal, and outputs the internal clock signal INCLK to the delay locked loop 240.

The first output driver 220 may include a pre-driver, and the second output driver 230 may include a main driver. In this case, the data DATA is outputted to the data pad DQ through the second output driver 230 under the control of the first output driver 220. Meanwhile, the second output driver 230 may include an off chip driver (OCD).

The delay locked loop 240 includes a delay line 241, a first replica delay unit 243, a second replica delay unit 245, a first phase comparator 247, and a first delay controller 249. The delay line 241 variably delays the internal clock signal INCLK by a third delay time tD3 and outputs a delay locked internal clock signal DLLCLK. The first replica delay unit 243 delays the delay locked internal clock signal DLLCLK by the modeled second delay time tD2 and outputs a first feedback clock signal FBCLK1. The second replica delay unit 245 delays the first feedback clock signal FBCLK1 by the modeled first delay time tD1 and outputs a second feedback clock signal FBCLK2. The first phase comparator 247 compares the phase of the internal clock signal INCLK with the phase of the second feedback clock signal FBCLK2. The first delay controller 249 controls a third delay time tD3 of the delay line 241 in response to an output signal of the phase comparator 247. Here, the first replica delay unit 243 and the second replica delay unit 245 are not designed to be the same as the actual circuits corresponding to the input buffer 210 and the first and second output drivers 220 and 230, but designed in molded forms. According to this exemplary embodiment, the first replica delay unit 243 is formed to have a varying second delay time tD2 under the control of a second delay controller 252 which will be described later. Therefore, the first replica delay unit 243 may be formed of a variable delay line. For example, the first replica delay unit 243 may include a dual coarse delay line (DCDL) and a fine phase mixer (FPM).

The delay time compensator 250 includes a second phase comparator 251, and a second delay controller 252. The second phase comparator 251 compares the phase of the output signal of the second output driver 230 with the phase of the first feedback clock signal FBCLK1 of the first replica delay unit 243. The second delay controller 252 controls the second delay time tD2 of the first replica delay unit 243 in response to an output signal of the second phase comparator 251.

Hereafter, an exemplary operation of the semiconductor memory device 200 according to this exemplary embodiment of the present invention having the above-described structure will be described.

In the condition that the delay amount of the first replica delay unit 243 is designed as the second delay time tD2 that occurs by the first and second output drivers 220 and 230 and the delay amount of the second replica delay unit 245 is designed as the first delay time tD1 that occurs by the input buffer 210, a tracking process is performed to control the third delay time tD3 needed for the delay locking of the delay line 241 and the second delay time tD2 of the first replica delay unit 243. The tracking process may be performed as follows.

Once the external clock signals CLK and CLKB are transferred to the delay line 241 as the internal clock signal INCLK after being buffered in the input buffer 210, the delay line 241 delays the internal clock signal INCLK by the third delay time tD3 corresponding to a default delay amount and outputs a delay locked internal clock signal DLLCLK.

In this situation, the first replica delay unit 243 receives a feedback signal, the delay locked internal clock signal DLLCLK of the delay line 241, delays the delay locked internal clock signal DLLCLK by the modeled second delay time tD2 to output the first feedback clock FBCLK1. Also, the second replica delay unit 245 delays the output signal FBCLK1 of the first replica delay unit 243 by the modeled first delay time tD1, and outputs the second feedback clock FBCLK2.

Then, the phase comparator 247 compares the phase of the internal clock signal INCLK outputted from the input buffer 210 with the phase of the second feedback clock FBCLK2 outputted from the second replica delay unit 245, and the delay controller 249 generates a first control signal CTR1 for controlling the third delay time tD3 in response to the comparison result of the phase comparator 247.

The delay line 241 delays the internal clock signal INCLK by the third delay time tD3 in response to the first control signal CTR1 and outputs the delay locked internal clock signal DLLCLK.

Meanwhile, the second phase comparator 251 receives a feedback signal, the output signal of the second output driver 230, and the first feedback clock FBCLK1 of the first replica delay unit 243, to compare them with each other and output a comparison result to the second delay controller 252. The second delay controller 252 outputs a second control signal CTR2 to the first replica delay unit 243 in response to the output signal of the second phase comparator 251. Accordingly, the first replica delay unit 243 delays the delay locked internal clock signal DLLCLK by the controlled second delay time tD2 in response to the second control signal CTR2. This is an exemplary operation for controlling the delay amount of the first replica delay unit 243 in correspondence to the changed second delay time tD2 which may be changed due to the conditions of processes, voltage, and/or temperature (PVT).

When the phase of the internal clock signal INCLK is synchronized with the phase of the second feedback clock FBCLK2 after repeating a series of the above operations, the third delay time tD3 of the delay line 241 may be delay locked. Here, after the tracking of the second delay time tD2 of the first replica delay unit 243 is completed, the tracking of the third delay time tD3 of the delay line 241 may be completed. This is because the delay amount of the first replica delay unit 243 is set to the second delay time tD2 that occurs in the first output driver 220 and the second output driver 230. Therefore, the time for tracking the delay amount of the first replica delay unit 243 to the second delay time tD2 that occurs by the first output driver 220 and the second output driver 230 may be shorter than the time for tracking the delay amount of the delay line 241 to the third delay time tD3 needed for delay locking.

In the state where the delay locked loop 240 is delay locked, when a memory cell (not shown) outputs the data DATA, the second output driver 230 synchronizes the data DATA with the delay locked internal clock signal DLLCLK under the control of the first output driver 220 and outputs a synchronized data to the data pad DQ.

Meanwhile, the second delay time tD2 of the first replica delay unit 243 and the third delay time tD3 of the delay line 241 may be updated at every update period. Since jitter may occur in the delay locked internal clock signal DLLCLK due to noise or the condition of processes, voltage and/or temperature (PVT) during the update process, the above tracking process is repeatedly performed to compensate for the jitter. Here, the update process may be performed onto the delay line 241 and the first replica delay unit 243 simultaneously or sequentially.

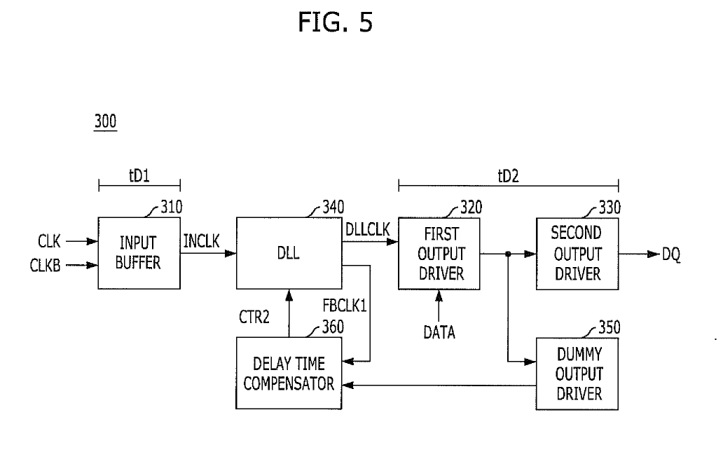

FIG. 5 is a block diagram illustrating a structure of a semiconductor memory device in accordance with another exemplary embodiment of the present invention.

This exemplary embodiment of the present invention provides a semiconductor memory device that may minimize the loading that may be applied to the data DATA outputted to the data pad DQ, compared with the previous exemplary embodiment.

Referring to FIG. 5, the semiconductor memory device 300 includes an input buffer 310, first and second output drivers 320 and 330, a delay locked loop (DLL) 340, a dummy output driver 350, and a delay time compensator 360. The input buffer 310 is included in an input path and receives external clock signals CLK and CLKB from the outside and outputs an internal clock signal INCLK. The first and second output drivers 320 and 330 are included in an output path and synchronize a data DATA outputted from a memory cell (not shown) with a delay locked internal clock signal DLLCLK and outputs a synchronized signal to a data pad DQ. The delay locked loop 340 receives the internal clock signal INCLK and generates the delay locked internal clock signal DLLCLK by reflecting a first delay time tD1 which occurs by the input buffer 310 and a second delay time tD2 which occurs in the first and second output drivers 320 and 330. The dummy output driver 350 mirrors the second delay time tD2 which occurs in the first and second output drivers 320 and 330 and outputs an output signal which is the same as the output signal of the second output driver 330. The delay time compensator 360 adjusts the second delay time tD2 by using a first feedback clock signal FBCLK1 reflecting the second delay time tD2 and an output signal of the dummy output driver 350.

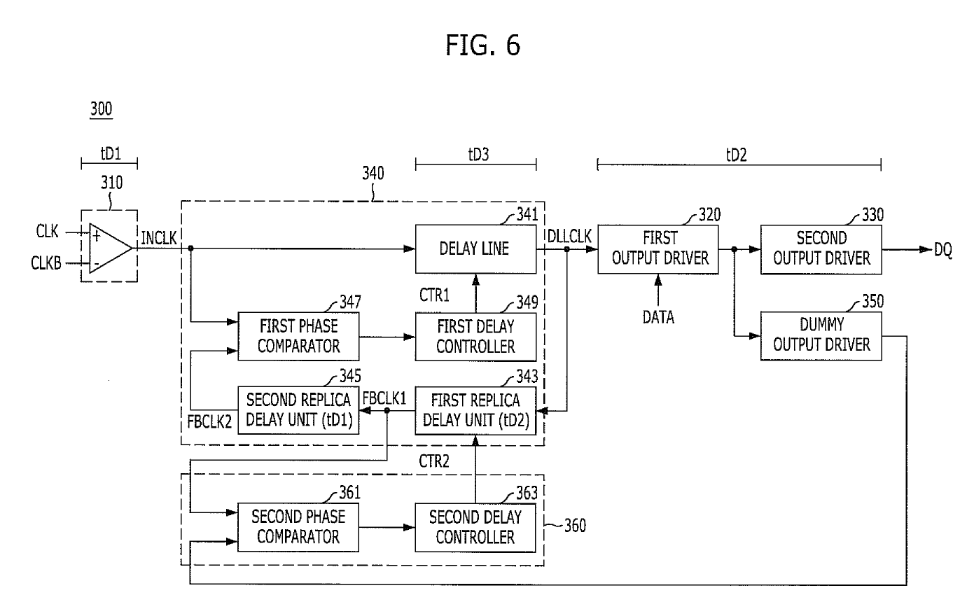

FIG. 6 is a detailed block diagram illustrating the semiconductor memory device of FIG. 5.

Referring to FIG. 6, the input buffer 310 receives the external clock signals CLK and CLKB inputted from the outside, generates an internal clock signal INCLK, which may be a single-ended signal, and outputs the internal clock signal INCLK to the delay locked loop 340.

The first output driver 320 may include a pre-driver, and the second output driver 330 may include a main driver. In this case, the data DATA is outputted to the data pad DQ through the second output driver 330 under the control of the first output driver 320. Meanwhile, the second output driver 330 may include an off chip driver (OCD).

The delay locked loop 340 includes a delay line 341, a first replica delay unit 343, a second replica delay unit 345, a first phase comparator 347, and a first delay controller 349. The delay line 341 variably delays the internal clock signal INCLK by a third delay time tD3 and outputs a delay locked internal clock signal DLLCLK. The first replica delay unit 343 delays the delay locked internal clock signal DLLCLK by the modeled second delay time tD2 and outputs a first feedback clock signal FBCLK1. The second replica delay unit 345 delays the first feedback clock signal FBCLK1 by the modeled first delay time tD1 and outputs a second feedback clock signal FBCLK2. The first phase comparator 347 compares the phase of the internal clock signal INCLK with the phase of the second feedback clock signal FBCLK2. The first delay controller 349 controls a third delay time tD3 of the delay line 341 in response to an output signal of the phase comparator 347. Here, the first replica delay unit 343 and the second replica delay unit 345 are not designed to be the same as the actual circuits corresponding to the input buffer 310 and the first and second output drivers 320 and 330, but designed in molded forms. According to this exemplary embodiment, the first replica delay unit 343 is formed to have a varying second delay time tD2 under the control of a second delay controller 363 which will be described later. Therefore, the first replica delay unit 343 may be formed of a variable delay line. For example, the first replica delay unit 343 may include a dual coarse delay line (DCDL) and a fine phase mixer (FPM).

The dummy output driver 350 is designed to be the same as the second output driver 330. The dummy output driver 350 receives the output signal of the first output driver 320 and outputs the substantially same output signal as the output signal of the second output driver 330.

The delay time compensator 360 includes a second phase comparator 351, and a second delay controller 363. The second phase comparator 351 compares the phase of the output signal of the dummy output driver 350 with the phase of the first feedback clock signal FBCLK1 of the first replica delay unit 343. The second delay controller 363 controls the second delay time tD2 of the first replica delay unit 343 in response to an output signal of the second phase comparator 351.

Hereafter, an exemplary operation of the semiconductor memory device 300 according to this exemplary embodiment of the present invention having the above-described structure will be described.

In the condition that the delay amount of the first replica delay unit 343 is designed as the second delay time tD2 that occurs by the first and second output drivers 320 and 330 and the delay amount of the second replica delay unit 345 is designed as the first delay time tD1 that occurs by the input buffer 310, a tracking process is performed to control the third delay time tD3 needed for the delay locking of the delay line 341 and the second delay time tD2 of the first replica delay unit 343. The tracking process may be performed as follows.

Once the external clock signals CLK and CLKB are transferred to the delay line 341 as the internal clock signal INCLK after being buffered in the input buffer 310, the delay line 341 delays the internal clock signal INCLK by the third delay time tD3 corresponding to a default delay amount and outputs a delay locked internal clock signal DLLCLK.

In this situation, the first replica delay unit 343 receives a feedback signal the delay locked internal clock signal DLLCLK of the delay line 341, delays the delay locked internal clock signal DLLCLK by the modeled second delay time tD2 to outputs the first feedback clock FBCLK1. Also, the second replica delay unit 345 delays the output signal FBCLK1 of the first replica delay unit 343 by the modeled first delay time tD1, and outputs the second feedback clock FBCLK2.

Then, the phase comparator 347 compares the phase of the internal clock signal INCLK outputted from the input buffer 310 with the phase of the second feedback clock FBCLK2 outputted from the second replica delay unit 345, and the delay controller 349 generates a first control signal CTR1 for controlling the third delay time tD3 in response to the comparison result of the phase comparator 347.

The delay line 341 delays the internal clock signal INCLK by the third delay time tD3 in response to the first control signal CTR1 and outputs the delay locked internal clock signal DLLCLK.

Meanwhile, the second phase comparator 361 receives a feedback signal, the output signal of the dummy output driver 350 and the first feedback clock FBCLK1 of the first replica delay unit 343, to compare them with each other, and outputs a comparison result to the second delay controller 363. The second delay controller 363 outputs a second control signal CTR2 to the first replica delay unit 343 in response to the output signal of the second phase comparator 361. Accordingly, the first replica delay unit 343 delays the delay locked internal clock signal DLLCLK by the controlled second delay time tD2 in response to the second control signal CTR2. This is an exemplary operation for controlling the delay amount of the first replica delay unit 343 in correspondence to the changed second delay time tD2 which may be changed due to the conditions of processes, voltage, and/or temperature (PVT).

When the phase of the internal clock signal INCLK is synchronized with the phase of the second feedback clock FBCLK2 after repeating a series of the above operations, the third delay time tD3 of the delay line 341 may be delay locked. Here, after the tracking of the second delay time tD2 of the first replica delay unit 343 is completed, the tracking of the third delay time tD3 of the delay line 341 may be completed. This is because the delay amount of the first replica delay unit 343 is set to the second delay time tD2 that occurs in the first output driver 320 and the second output driver 330. Therefore, the time for tracking the delay amount of the first replica delay unit 343 to the second delay time tD2 that occurs by the first output driver 320 and the second output driver 330 may be shorter than the time for tracking the delay amount of the delay line 341 to the third delay time tD3 needed for delay locking.

In the state where the delay locked loop 340 is delay locked, when a memory cell (not shown) outputs the data DATA, the second output driver 330 synchronizes the data DATA with the delay locked internal clock signal DLLCLK under the control of the first output driver 320 and outputs a synchronized data to the data pad DQ.

Meanwhile, the second delay time tD2 of the first replica delay unit 343 and the third delay time tD3 of the delay line 341 may be updated at every update period. Since jitter may occur in the delay locked internal clock signal DLLCLK due to noise or the condition of processes, voltage and/or temperature (PVT) during the update process, the above tracking process is repeatedly performed to compensate for the jitter. Here, the update process may be performed onto the delay line 341 and the first replica delay unit 343 simultaneously or sequentially.

According to the exemplary embodiments of the present invention, the data DATA outputted to the outside through the data pad DQ may be more precisely aligned to a clock edge of the external clock signals CLK and CLKB. Meanwhile, since the second delay time tD2 that occurs in an output circuit is relatively longer than the first delay time tD1 that occurs in the input circuit in the exemplary embodiments of the present invention, the data DATA may be more precisely aligned to a clock edge of the external clock signals CLK and CLKB by controlling the delay amount of the first replica delay unit which models the second delay time tD2 that occurs in an output circuit.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a delay locked loop including a replica delay unit which is configured to delay a signal reflecting a delay amount of an output path of a signal; and
a delay time compensator configured to compensate for a difference of a delay time between the replica delay unit and the output path by comparing an output signal of the replica delay unit and an output signal of the output path.

2. The semiconductor device of claim 1, wherein the delay time compensator comprises:
a phase comparator configured to compare a phase of the output signal of the replica delay unit and the output signal of the output path; and
a delay controller configured to control a delay time of the replica delay unit according to a comparison result of the phase comparator.

3. A semiconductor device, comprising:
a delay line configured to delay a internal clock signal;
an output path configured to receive an output clock signal of the delay line, and output a delay locked internal clock signal to an outside;
a first replica delay unit configured to generate a first feedback clock signal by delaying the output clock signal of the delay line;
a second replica delay unit configured to generate a second feedback clock signal by delaying the first feedback clock signal;
a first phase comparator configured to compare the internal clock signal and the second feedback clock signal;
a first delay controller configured to control a delay amount of the delay line according to the comparison result of the first phase comparator;
a second phase comparator configured to compare the delay locked internal clock signal and the first feedback clock signal; and
a second delay controller configured to adjust a delay amount of the first replica delay unit according to the comparison result of the second phase comparator.

4. The semiconductor device of claim 3, wherein the first replica delay is configured to reflect a delay element of the output path, and the second replica delay is configured to reflect a delay element of an input path which receives an external clock signal from outside and output the internal clock signal.

5. The semiconductor device of claim 3, wherein the first replica delay unit comprises a dual coarse delay line (DCDL) and a fine phase mixer (FPM).

6. A semiconductor device, comprising:
a delay locked loop including a replica delay unit which is configured to delay a signal reflecting a delay amount of an output path of a signal;
a dummy output path configured to output a dummy output signal, wherein the dummy output signal has the substantially same phase as an output signal of the output path; and
a delay time compensator configured to compensate for a difference of a delay time between the replica delay unit and the output path by comparing an output signal of the replica delay unit and the dummy output signal.

7. The semiconductor device of claim 6, wherein the dummy output path is configured to be the same as a final output unit included in the output path and receive the same input signal of the final output unit.

8. The semiconductor device of claim 6, wherein the output path comprises an off chip driver (OCD).

9. The semiconductor device of claim 6, wherein the delay time compensator comprises:
a phase comparator configured to compare a phase of the dummy output signal and a phase of the output signal of the replica delay unit; and
a delay controller configured to control the delay time of the replica delay unit according to a comparison result of the phase comparator.

10. The semiconductor device of claim 6, wherein the replica delay unit comprises a dual coarse delay line (DCDL) and a fine phase mixer (FPM).
